(19) United States
(12) Patent Application Publication
(10) Pub. No.: US 2014/0027714 A1
(43) Pub. Date: Jan. 30, 2014

(54) QUANTUM WELL THERMOELECTRIC COMPONENT FOR USE IN A THERMOELECTRIC DEVICE

(71) Applicants: Daniel Delprat, Crolles (FR); Christophe Figuet, Crolles (FR); Oleg Kononchuk, Grenoble (FR)

(72) Inventors: Daniel Delprat, Crolles (FR); Christophe Figuet, Crolles (FR); Oleg Kononchuk, Grenoble (FR)

(73) Assignee: SOITEC, Crolles Cedex (FR)

(21) Appl. No.: 14/004,541

(22) PCT Filed: Apr. 4, 2012
(86) PCT No.: PCT/IB12/00689

§ 371 Date: Oct. 17, 2013

(30) Foreign Application Priority Data
Apr. 14, 2011 (FR) 1153250

(51) Int. Cl. H01L 35/02; H01L 35/34

(52) U.S. Cl. CPC H01L 35/02; H01L 35/34
USPC 257/14; 438/54

(57) ABSTRACT

A quantum well thermoelectric component for use in a thermoelectric device based on the thermoelectric effect,
comprising a stack of layers of two materials respectively made on the basis of silicon and silicon-germanium,
the first of the two materials, made on the basis of silicon, defining a barrier semiconductor material and
the second of the two materials, made on the basis of silicon-germanium, defining a conducting semiconductor material,
the barrier semiconductor material having a band gap higher than the band gap of the conducting semiconductor material, wherein
the conducting semiconductor material is an alloy comprising silicon, germanium and at least a lattice-matching element, the lattice-matching element(s) being present in order to control a lattice parameter mismatch between the barrier layer made of the barrier semiconductor material and the conducting layer made of the conducting semiconductor material.

### CROSS-REFERENCE TO RELATED APPLICATIONS

This application is a national phase entry under 35 U.S.C. §371 of International Patent Application PCT/IB2012/000689, filed Apr. 4, 2012, designating the United States of America and published in English as International Patent Publication WO 2012/140483 A1 on Oct. 18, 2012, which claims the benefit under Article 8 of the Patent Cooperation Treaty and under 35 U.S.C. §119(e) to French Patent Application Serial No. 1153250, filed Apr. 14, 2011, the disclosure of each of which is hereby incorporated herein by this reference in its entirety.

### TECHNICAL FIELD

This invention relates to thermoelectric devices based on the thermoelectric effect and, in particular, to thermoelectric materials and thermoelectric components for such devices.

### BACKGROUND

Thermoelectric devices are used for cooling and heating and the generation of electricity. Generation of electricity in a thermoelectric device is based on the Seebeck effect, and uses a cold side and a hot side. Thermoelectric conversion efficiency is measured by the following formula:

$$η = \frac{Δ T}{{T}_{hot}} \frac{\sqrt{1 + Z \overline{T} - 1}}{\sqrt{1 + Z \overline{T} +} \frac{{T}_{cold}}{{T}_{hot}}} with Δ T = {T}_{hot} - {T}_{cold} and$$

$$\overline{T} = \frac{{T}_{hot} + {T}_{cold}}{2}$$

where Tₕₒₜ is the temperature of the hot side and T_{cold} is the temperature of the coldside, and Z is called the figure of merit and is defined by:

$$Z = \frac{{S}^{2} σ}{κ}$$

where S is the Seebeck coefficient S=ΔV/ΔT, σ is the material electricalconductivity, and κ is the material thermal conductivity. The higher the Z value, the higher the conversion efficiency η. A conventional material is Bi₂Te₃. Other materials such as Bi₁₋ₓSbₓ or PbTe are also used.

Semiconductor superlattices, made of multilayer layers of semiconductor material, are possible structures to serve for thermoelectric devices. A quantum well (QW) is created where a layer of semiconductor conducting material with a first band gap is sandwiched between two layers of barrier semiconductor material having a higher band gap than the band gap of the conducting material. Superlattices can thus define multiple quantum wells (MQW).

Quantum wells are intended to confine carriers in the conducting layer. An increased Seebeck coefficient and electrical conductivity is expected, resulting in particular from an increase of density of states through quantum confinement. This leads to an increase of the Z value and consequently an improved thermoelectric conversion.

Different types of materials have been considered up to now to provide superlattices for thermoelectric applications, such as successive layers of B₄C and B₉C. A superlattice made of alternating layers of Si/Si_{0.8}Ge_{0.2} seems to be a good candidate for thermoelectric applications.

A high quality semiconductor material is required since the carrier diffusion due to crystal defects is detrimental to the thermoelectric properties of the material.

Prior art discloses Si₁₋ₓGeₓ/Si multiple quantum wells system manufactured mainly by using:
sputtering; or
epitaxial growth techniques.

Sputtering techniques cannot ensure the continuation of the crystal structure of the seed. In order to achieve the growth of a mono crystal structure where the crystal quality is controlled, epitaxial growth techniques are preferred, although they might be more expensive.

However, even epitaxial growth techniques may result in a very defective material because of defects such as dislocations that can appear in the material.

The dislocations are more likely to appear in a material where thicknesses of the layers are beyond a threshold thickness called the critical layer thickness and/or where the stack of layers becomes too thick.

This critical layer thickness depends on many parameters, such as the intrinsic properties of the material, the strain the material is subjected to, the other materials the surrounding layers are made of and their respective properties and thicknesses, or the overall thickness of a stack of layers.

Therefore, an epitaxially grown material whose layer thickness is beyond critical thickness shows defects such as dislocation. These defects may degrade significantly the material performance such as electrical conductivity, and consequently thermoelectric conversion efficiency.

In the case of a thermoelectric generator, including Si_{0.8}Ge_{0.2}/Si grown on Si wafer, with a barrier and conducting layer thickness of around 10 nm, and a superlattice thickness of a few micrometers (typically 10 μm), defects such as dislocations appear in the material.

Therefore, there is a need for an epitaxially grown thermoelectric material with a critical layer thickness above the required operational thickness in order to obtain a material with a high figure of merit Z.

When the lattice parameter of an epitaxial layer is different from the lattice parameter of the substrate upon which the layer grows, the layer lattice deforms to adjust its lattice parameter to match the lattice parameter of the substrate. This causes an increase of elastic energy in the layer. At critical layer thickness, this elastic energy is higher than the energy needed to create crystal defects (such as dislocations), and the overgrown layer starts to relax elastic energy by nucleating dislocations.

### DISCLOSURE

The present invention provides a high quality epitaxially grown stack of layers, comprising a lattice matching element for controlling the mismatch of the lattice parameters of the layers. For example, the conducting layers include a lattice matching element to match the lattice parameter of the barrier layers and/or the substrate.

According to a first aspect, the present invention thus provides a quantum well thermoelectric component for use in a thermoelectric device based on the thermoelectric effect,
comprising a stack of layers of two materials respectively made on the basis of silicon and silicon-germanium,
the first of the two materials, made on the basis of silicon, defining a barrier semiconductor material and
the second of the two materials, made on the basis of silicon-germanium, defining a conducting semiconductor material,
the barrier semiconductor material having a band gap higher than the band gap of the conducting semiconductor material, wherein
the conducting semiconductor material is an alloy comprising silicon, germanium and at least a lattice-matching element, the lattice-matching element(s) being present in order to control a lattice parameter mismatch between the barrier layer made of the barrier semiconductor material and the conducting layer made of the conducting semiconductor material.

Other preferred, although non-limitative, features of the thermoelectric component are as follows:
the lattice-matching element is carbon, or boron, or a mix of carbon and boron;
the conducting semiconductor material is Si₁₋ₓGe_{x-α-β}C_{α}B_{β}, wherein
   0<x≦1
   0≦α≦x/9
   0≦β≦x/9
   0<α+β≦x/9
and
   0≦α≦0.04
   0≦β≦0.01
   0<α+β<0.05
   the total number of atoms of the lattice-matching element(s) is comprised between 9% and 10% of the number of atoms of germanium;
   the quantum well thermoelectric component further comprises a substrate on which the stack of layers is arranged;
   the substrate is a low thermal conducting substrate having a thermal conductivity under 2 W·m⁻¹·K⁻¹;
   the substrate is made of glass;
   the stack of layers comprises at least 50 layers, the thickness of the layers being comprised between 50 Å and 300 Å.

According to a second aspect, the present invention also provides a method for manufacturing a quantum well thermoelectric component according to the first aspect, wherein the stack of layers is grown by epitaxy on a substrate of silicon.

The method may further comprise the following features:
the stack of layers can then be transferred onto a low thermal conductive substrate, or
the substrate of silicon can be a mono crystalline silicon layer disposed at the surface of a low thermal conductive substrate before the growth by epitaxy of the stack of layers.

According to a third aspect, the present invention also provides a thermoelectric device comprising at least a quantum well thermoelectric component according to the first aspect of the invention.

### BRIEF DESCRIPTION OF THE DRAWINGS

Other aspects, objects and advantages of the present invention will become better apparent upon reading the following detailed description of preferred embodiments thereof, given as non-limiting examples, and made with reference to the appended drawings wherein:

FIG. 1 is a schematic illustration of the structure of the quantum well thermoelectric component for use in a thermoelectric device according to the first aspect of the invention.

FIG. 2 is a graph showing the critical layer thickness in Å in a logarithmic scale in regard to the percentage of germanium in the conducting semiconductor material for a different percentage of carbon added to the conducting semiconductor material.

FIG. 3 is a schematic illustration of the structure of a thermoelectric device incorporating the quantum well thermoelectric component.

### DETAILED DESCRIPTION

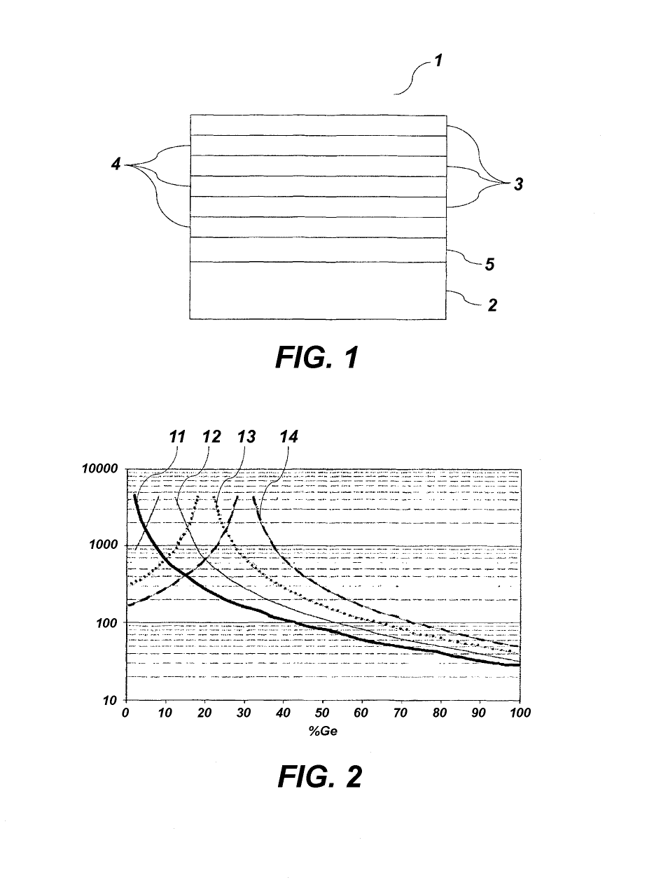

A thermoelectric component for use in a thermoelectric device is provided and will now be described with reference to FIG. 1. A thermoelectric component is a component for a thermoelectric device, the component having thermoelectrical properties suitable for the thermoelectric device. This thermoelectric component comprises a stack of layers 1 of semiconductor materials, thus defining a semiconductor superlattice.

The stack of layers 1 comprises layers 3, 4 of at least two different semiconductor materials: a first semiconductor material and a second semiconductor material, respectively made on the basis of silicon and silicon-germanium. A material made on the basis of a chemical element is a material comprising a majority of atoms of this chemical element, possibly with the addition of atoms of one or more other chemical elements.

The first semiconductor material has a band gap higher than the band gap of the second semiconductor material. The first of the two materials thus defines a barrier semiconductor material and the second of the two materials defines a conducting semiconductor material.

Alternating layers 3, 4 of the barrier semiconductor material and the conducting semiconductor material respectively define barrier layers 3 and conducting layers 4, thus defining a quantum well structure.

Alternatively, layers constituted of other materials may be located in this stack of layer 1, provided they do not prevent the stack 1 of layers from defining a quantum well structure.

The thickness of the layers 3, 4 is preferably comprised between 50 and 300 Å, but may be of any value suitable to achieve a quantum well superlattice. The thickness may be chosen differently, depending on the materials used and the properties intended to be achieved.

In order to achieve a quantum well stack 1 of layers thick enough to be used in a thermoelectric device, the barrier semiconductor material and the conducting semiconductor material are chosen to have the same crystal structure. For example, both silicon, as the barrier semiconductor material, and an alloy of silicon and germanium, as conducting semiconductor material, have a cubic crystal structure.

However, silicon and germanium have different lattice parameters, resulting in an alloy of silicon and germanium having a lattice parameter different from the lattice parameter of pure silicon.

In the case of a monocrystal stack 1 of layers grown by epitaxy, the lattice parameters of the semiconductor materials of the layers 3, 4 constituting the stack 1 of layers may be different from the normal intrinsic lattice parameters of the semiconductor materials. Indeed, the lattice parameters of the material of each layer 3, 4 adapt to ensure a continuity of the lattice parameter.

As a consequence, alternating layers 3, 4 of materials such as silicon and silicon-germanium will result in layers 3, 4 being strained, thus likely to show strain-induced defects such as dislocations if their thicknesses exceed their critical layer thicknesses.

In order to prevent such defects from being caused by non-matched lattice parameters between the lattice parameter of the conducting material constituting the conducting layers 4 and the lattice parameter of the barrier material constituting the barrier layers 3 and/or the substrate, atoms of at least one lattice-matching element is present in some layers of the stack 1, for example, in the conducting layers 4.

Lattice-matching element atoms take place in the crystal structure of the semiconductor material. The lattice-matching element is chosen to be able to modify the lattice parameter of the conducting layer 4 material so as to reduce the difference between the lattice parameters of the barrier semiconductor layer 3 material and the conducting semiconductor layer 4 material. The atoms of the lattice-matching element(s) replace some of the atoms of the crystal structure of the semiconductor material they are incorporated in, without altering the type of crystal structure of the semiconductor material.

The amount of lattice-matching element incorporated in the conducting material depends on the respective lattice parameters of the barrier semiconductor layer 3 material and the conducting semiconductor layer 4 material.

For example, when considering a stack of layers 1 made of alternating layers of silicon (Si) as the barrier material and silicon-germanium (Si₁₋ₓGeₓ) as the conducting material, the lattice-matching element may be carbon (C). Carbon atoms replace germanium atoms on the same place in the crystal structure of the conducting layer 4.

FIG. 2 is a graph showing the critical layer thickness in Å in a logarithmic scale in regard to the percentage of germanium in the conducting semiconductor material for different percentage of carbon added to the conducting semiconductor material. The abscissa axis represents the percentage of germanium (Ge) in a ternary alloy of silicon, germanium and carbon constituting the conducting layers 4 of a stack of layers 1. The ordinate axis represents the thickness in Å in a logarithmic scale.

The curves show the critical layer thickness for different carbon content in the conducting semiconductor material:
the thick curve 11 for 0% of carbon;
the thin curve 12 for 1% of carbon;
the dotted curve 13 for 2% of carbon;
the dashed curve 14 for 3% of carbon.

The band structure of SiGe or SiGe layers 4 alternating with Si layers 3 allows the confinement of holes in the conducting layers 4. The holes confinement is improved with high Ge contents. Therefore, it is highly desirable to have a high Ge content.

Typically, Ge content is intended to be above 1% of the total number of atoms of the conducting semiconductor material.

However, without a lattice-matching element as illustrated by the thick curve 11, the critical layer thickness decreases as the Ge content increases.

As illustrated by FIG. 2, the carbon atoms in the conducting material allow a higher critical layer thickness for higher Ge contents than without carbon (thick curve 11). Consequently, it is possible to have a high Ge content while having a high critical layer thickness by virtue of a lattice-matching element, such as carbon.

Further, the critical layer thickness is significantly raised by introducing a number of carbon atoms comprised between 9% and 10% of the number of atoms of germanium. As an example, for an Si—Ge alloy with 20% of germanium as a conducting layer material, it is desirable to add from 1.8% to 2% of carbon atoms to have an increased critical layer thickness for this layer. Therefore, it is desirable to have a total number of atoms of the lattice-matching element(s) comprised between 9% and 10% of the number of atoms of germanium.

By introducing carbon atoms, the lattice parameter of the silicon-germanium conducting layer 4 material is changed to match the lattice parameter of the silicon material constituting the barrier layer 3 so as to reduce the strain induced by the mismatch of the intrinsic lattice parameters of the two materials.

This allows the epitaxial growth of stacks 1 of layers 3, 4 with layer thicknesses below the critical layer thickness. Therefore, thicker layers 3, 4 and thicker stacks 1 of layers 3, 4 can be obtained without crystal defects.

Further, by growing the stack of layers on a thin monocrystalline silicon layer 5, the lattice parameters of the conducting semiconductor layers 4, the barrier semiconductor layers 3 and the silicon layer 5 will be matched.

Boron (B) may also be used as a lattice-matching element. Indeed, boron atoms have a radius close to the radius of carbon atoms. In fact, boron atoms may be used with the same proportion as carbon atoms, namely, a number of boron atoms comprised, for example, between 9% and 10% of the number of germanium atoms.

Carbon as a lattice-matching element has no substantial effect on the electrical properties of the silicon-germanium conducting material. On the opposite, boron will have a doping effect on the semiconducting properties of the material.

A mix of carbon and boron may be used as a lattice-matching element in order to achieve desired semiconducting properties for the conducting semiconductor material. The matching of the lattice parameters requires that the same proportion is to be observed for the mix of carbon-boron as for carbon or boron alone. In other words, the sum of the number of atoms of carbon and of the number of atoms of boron is preferably to be comprised between 9% and 10% of the number of germanium atoms.

However, the proportion of matching elements may differ from what is needed for matching the lattice parameter in order to keep a strain in the conducting semiconductor layers 4. A strain may be desirable to improve the electrical mobility. The amount of lattice-matching element incorporated into the conducting semiconductor material must, nevertheless, be high enough to ensure that the critical layer thickness is raised beyond the thickness of the layers 3, 4.

The proportion of atoms of lattice-matching element is preferably above 0.1% of the total number of atoms of the conducting semiconductor material.

Following the same example of an alloy of silicon, germanium and at least a lattice-matching element as the conducting semiconductor material, the conducting material may comprise silicon (Si), germanium (Ge), carbon (C) or boron (B) according to the following formula: Si₁₋ₓGe_{x-α-β}C_{α}B_{β}, wherein x, α and β are real numbers and
0<x<1
0≦α<x/9
0<β≦x/9
0<α+β≦x/9.

Further, the respective maximum solubility of carbon and boron must be considered, i.e., their respective maximum amount that can be incorporated in a Si—Ge alloy. The maximum amount of carbon in percentage of atoms in the final alloy is about 4%, whereas the maximum amount of boron in percentage of atoms in the final alloy is about 1%. Therefore, the maximum amount of the mix of carbon-boron in percentage of atoms in the final alloy is about 5%.

As a consequence, the numbers α and β also have the corresponding boundaries:
0≦α≦0.04
0≦β≦0.01
0<α+β≦0.05

Preferably, 0.001<α+β so as to allow an efficient lattice matching and 0.01<x so as to allow an efficient hole confinement. Further, it shall be noted that, necessarily, α+β<x.

Preferably, the total proportion of matching element(s) α+β is superior or equal to x/10:
x/10≦α+β≦x/9

The quantum well thermoelectric component according to the first aspect of the invention may further comprise a thin monocrystalline silicon layer 5 on which the stack 1 of layers 3, 4 is arranged, the thin monocrystalline silicon layer 5 being disposed or formed, e.g., by deposition, on a substrate 2.

The substrate 2 is preferably a low thermal conducting substrate, preferably below 2 W·m⁻¹·K⁻¹, such as a glass substrate.

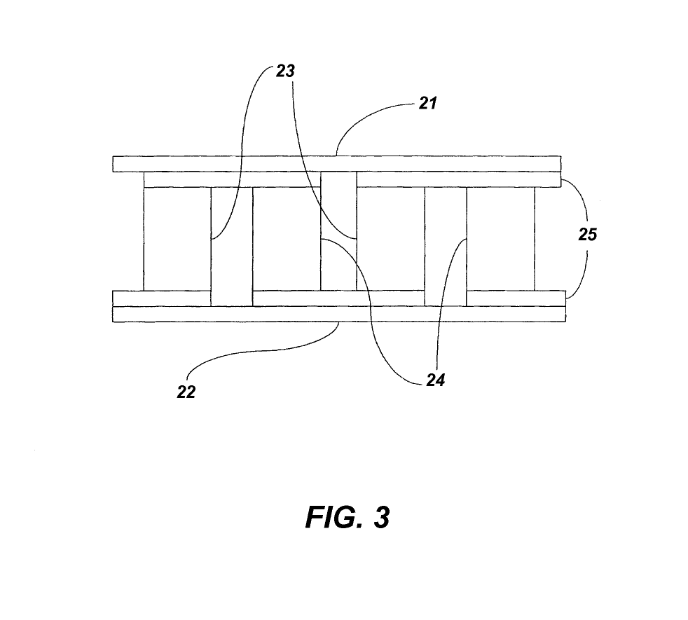

FIG. 3 shows a part of a thermoelectric device where a hot side 21 and a cold side 22, generally of metal, are separated by a plurality of quantum well thermoelectric components 23, 24 as described above.

The thermal flow is directed from the hot side 21 to the cold side 22 if the thermoelectric device is used as a generator. The thermal flow is directed from the cold side 22 to the hot side 21 should the thermoelectric device be used as a heat exchanger.

The plurality of quantum well thermoelectric components 23, 24 can be classified in two types of components, the n-type component 23 and the p-type component 24, depending on the dopants incorporated in the semiconductor materials constituting the layers.

Doping is well known by the person having ordinary skill in the art. For example, the aforementioned Si—Ge layers may be boron doped for p-type component, and phosphorous, arsenic or antimony doped for n-type component. Alternatively, different semiconductor material may be used for p-type and n-type components 23, 24.

The n-type quantum well thermoelectric components 23 and the p-type quantum well thermoelectric components 24 are alternately disposed and electrically connected by an electrically conductive material 25 so as to pair, or couple, a first end of an n-type component 23 with a first p-type component 24 and a second end of an n-type component 23 with a second p-type component 24 and vice versa. The layers of the components 23, 24 are perpendicular to the conductive material 25 and parallel to the thermal flow.

According to a second aspect, the present invention also provides a method for manufacturing a stack of layers of a quantum well thermoelectric component, the stack of layers comprising at least two different semiconductor materials respectively made on the basis of silicon and silicon-germanium, the first of the two materials defining a barrier semiconductor material and the second of the two materials defining a conducting semiconductor material, the barrier semiconductor material having a band gap higher than the band gap of the conducting semiconductor material.

The stack of layers is grown by epitaxy on a Si substrate. Every suitable epitaxy technique may be used, such as chemical vapor deposition (CVD) or molecular beam epitaxy (MBE). As described above, epitaxy is employed in order to obtain a high quality material without crystal defects.

At least one lattice-matching element is incorporated to the conducting semiconductor material to control the lattice parameter of the conducting semiconductor material, the lattice-matching element being able to modify the lattice parameter of the conducting semiconductor material.

The barrier semiconductor material is made on the basis of silicon and the conducting semiconductor material is made on the basis of silicon-germanium. More precisely, the conducting semiconductor material is an alloy comprising silicon, germanium and at least a lattice-matching element, the lattice-matching element(s) being present in order to control a lattice parameter mismatch between the barrier layer 3 material and the conducting layer 4 material.

In this case, the total number of atoms of the lattice-matching element is preferably comprised between 9% and 10% of the number of atoms of germanium. However, the proportion may differ to keep a strain in the conducting semiconductor material. A strain may be desirable to improve the electrical mobility. The amount of lattice-matching element incorporated into the conducting semiconductor material must nevertheless be high enough to ensure that the critical layer thickness is raised beyond the thickness of the layers.

The lattice-matching element(s) may be carbon, boron, or a mix of carbon and boron. Following the same example of a conducting semiconductor material comprising an alloy of silicon, germanium and at least a lattice-matching element as the conducting semiconductor material, the conducting material may comprise silicon (Si), germanium (Ge), carbon (C) or boron (B) according to the following formula: Si₁₋ₓGe_{x-α-β}C_{α}B_{β}, wherein x, α and β are real numbers and
0<x<1
0≦α≦x/9
0≦β≦x/9
0<α+β≦x/9

and
0≦α≦0.04
0≦β≦0.01
0<α+β≦0.05

Preferably, 0.001<α+β so as to allow an efficient lattice matching and 0.01<x so as to allow hole confinement.

Preferably, the total proportion of matching element(s) α+β is superior or equal to x/10:
x/10≦α+β≦x/9

The thickness of the layers is preferably comprised between 50 and 300 Å, but may be of any value appropriate for quantum well superlattices.

In the case of Si—SiGe superlattice, the stack 1 of layer 3, 4 is to be grown on a silicon substrate. This silicon substrate may be a thin monocrystalline silicon layer 5 disposed or formed on a low thermal conductive substrate 2 such as glass.

Alternatively, the stack of layers can be transferred from the silicon substrate on which it has been grown onto a low thermal conductive substrate 2, by any suitable method employed in silicon-on-insulator technology (SOI). For example, the SMARTCUT™ or SMARTSTACKING™ technology developed by SOITEC may be used.

According to the SMARTCUT™ process, a device layer disposed on a donor substrate is bonded onto a handle substrate, then the device layer is separated from the donor substrate by the expansion of hydrogen atoms implanted in a portion of the donor substrate. The device layer is then transferred onto the handle substrate.

According to the SMARTSTACKING™ process, a device layer disposed on a donor substrate is bonded onto a handle substrate. Then, the donor substrate is removed by a combination of wafer grinding and chemical etching. The device layer is then transferred onto the handle substrate.

1.-14. (canceled)

15. A quantum well thermoelectric component for use in a thermoelectric device based on the thermoelectric effect, comprising: a stack of alternating layers of two materials, a first material of the two materials comprising Si or a Si-based material and a second material of the two materials comprising SiGe or a SiGe-based material, the first material of the two materials defining barrier semiconductor layers in the stack of alternating layers, the second material of the two materials defining conducting semiconductor layers in the stack of alternating layers, the barrier semiconductor layers having band gaps higher than band gaps of the conducting semiconductor layers, wherein the second material of the two materials comprises an alloy including silicon, germanium, and at least one lattice-matching element, the at least one lattice-matching element reducing a lattice parameter mismatch between the barrier semiconductor layers and the conducting semiconductor layers.

16. The quantum well thermoelectric component of claim 15, wherein the at least one lattice-matching element is carbon.

17. The quantum well thermoelectric component of claim 15, wherein the at least one lattice-matching element is boron.

18. The quantum well thermoelectric component of claim 15, wherein the at least one lattice-matching element is a mix of carbon and boron.

19. The quantum well thermoelectric component of claim 15, wherein the conducting semiconductor material is Si₁₋ₓGe_{x-α-β}C_{α}B_{β}, wherein
0<x≦1
0≦α≦x/9
0≦β≦x/9
0<α+β≦x/9
and
0≦α≦0.04
0≦β≦0.01
0<α+β≦0.05

20. The quantum well thermoelectric component of claim 15, wherein a total number of atoms of the at least one lattice-matching element is between 9% and 10% of a total number of atoms of germanium in the second material of the two materials.

21. The quantum well thermoelectric component of claim 15, further comprising a substrate on which the stack of alternating layers is arranged.

22. The quantum well thermoelectric component of claim 21, wherein the substrate comprises a low thermal conductivity substrate having a thermal conductivity under 2 W·m⁻¹·K⁻¹.

23. The quantum well thermoelectric component of claim 21, wherein the substrate comprises glass.

24. The quantum well thermoelectric component of claim 21, wherein the stack of alternating layers comprises at least 50 layers, a thickness of each layer of the stack of alternating layers being between 50 Å and 300 Å.

25. A method for manufacturing a quantum well thermoelectric component, comprising:
eptixially depositing a stack of alternating layers of two materials on a substrate, a first material of the two materials comprising Si or a Si-based material and a second material of the two materials comprising SiGe or a SiGe-based material, the first material of the two materials defining barrier semiconductor layers in the stack of alternating layers, the second material of the two materials defining conducting semiconductor layers in the stack of alternating layers, the barrier semiconductor layers having band gaps higher than band gaps of the conducting semiconductor layers, wherein the second material of the two materials comprises an alloy including silicon, germanium, and at least one lattice-matching element, the at least one lattice-matching element reducing a lattice parameter mismatch between the barrier semiconductor layers and the conducting semiconductor layers.

26. The method of claim 25, wherein eptixially depositing the stack of alternating layers of two materials on the substrate comprises eptixially depositing the stack of alternating layers of two materials on a silicon substrate.

27. The method of claim 25, further comprising transferring the stack of alternating layers from the substrate onto a low thermal conductivity substrate.

28. The method of claim 25, wherein eptixially depositing the stack of alternating layers of two materials on the substrate comprises eptixially depositing the stack of alternating layers of two materials on a monocrystalline silicon layer disposed at a surface of a low thermal conductivity substrate.

29. The method of claim 25, further comprising selecting the at least one lattice-matching element to be carbon.

30. The method of claim 25, further comprising selecting the at least one lattice-matching element to be boron.

31. The method of claim 25, further comprising selecting the at least one lattice-matching element to be a mix of carbon and boron.

32. The method of claim 25, further comprising selecting the conducting semiconductor material to be Si₁₋ₓGe_{x-α-β}C_{α}B_{β}, wherein
0<x≦1
0≦α≦x/9
0≦β≦x/9
0<α+β≦x/9
and
0≦α≦0.04
0≦β≦0.01
0<α+β≦0.05

33. The method of claim 25, wherein a total number of atoms of the at least one lattice-matching element is between 9% and 10% of a total number of atoms of germanium in the second material of the two materials.

34. The method of claim 25, further comprising selecting the substrate to comprise a low thermal conductivity substrate having a thermal conductivity under 2 W·m⁻¹·K⁻¹.

35. The method of claim 25, further comprising selecting the substrate to comprise glass.
